(19) United States
(12) Patent Application Publication
(10) Pub. No.: US 2014/0192295 A1
(43) Pub. Date: Jul. 10, 2014

(54) METHOD OF FORMING A LIQUID CRYSTAL ALIGNMENT LAYER, METHOD OF MANUFACTURING A DISPLAY PANEL, AND A DISPLAY PANEL

(71) Applicant: WINTEK CORPORATION, Taichung City (TW)

(72) Inventors: Kuan-Hsien Wu, Changhua County (TW); Guan-Ren Wang, Tainan City (TW); Hsien-Wei Chiang, Taipei City (TW); Chi-Jen Lin, Yunlin County (TW); Chih-Yuan Wang, Taichung City (TW)

(73) Assignee: WINTEK CORPORATION, Taichung City (TW)

(21) Appl. No.: 14/150,727

(22) Filed: Jan. 8, 2014

(30) Foreign Application Priority Data
Jan. 9, 2013 (TW) 102100718

(51) Int. Cl. G02F 1/1337; H01L 51/52; H01L 51/56

(52) U.S. Cl. CPC G02F 1/133711; H01L 51/56; H01L 51/52
USPC 349/69; 349/124; 349/106; 438/30; 427/162

(57) ABSTRACT

A method of forming a liquid crystal alignment layer includes the following steps. A substrate is provided. A base layer is then formed on the substrate. A first liquid crystal alignment layer is formed on the base layer. The first liquid crystal alignment layer includes a plurality of first organic molecules. Each of the first organic molecules includes a first carboxyl group part and a first alkyl group part. A display panel includes the substrate, a counter substrate, a liquid crystal layer, and the first liquid crystal alignment layer. The substrate is disposed opposite to the counter substrate. The liquid crystal layer is disposed between the substrate and the counter substrate. The first liquid crystal alignment layer is disposed between the liquid crystal layer and the substrate.

### BACKGROUND OF THE INVENTION

1. Field of the Invention

The present invention relates to a method of forming a liquid crystal alignment layer, a method of forming a display panel and a display panel, and more specifically, to a method of forming a liquid crystal alignment layer by using organic molecules with carboxyl groups and first alkyl groups, a method of forming a display panel by using the liquid crystal alignment layer and a display panel including the liquid crystal alignment layer.

2. Description of the Prior Art

As liquid crystal displays (LCDs) have advantages of small volume and light weight, they are used in various electrical products, such as cell phones, personal digital assistances (PDAs), and notebooks. Since large-size LCDs have quickly developed, LCDs have become the main stream in the display market.

Generally, in liquid crystal display panels, alignment layers are needed to be formed on the contacted surface of the liquid crystal layer so as to control the pretilt angle when the liquid crystal molecules are driven or un-driven. Currently, a common method to form a liquid crystal alignment layer comprises forming a polyimide (polyimide, PI) film and performing a rubbing process and a baking process on the PI film, so that the liquid crystal molecules can be arranged along with a rubbing direction of the PI film. However, since the baking process is set at high temperatures (typically about 180° C. or more), the PI cannot be used as a liquid crystal alignment layer on plastic substrates and substrates having organic light emitting elements, since they cannot withstand such high temperatures. In addition, a photo alignment method using a UV light for irradiating monomer to form the vertical alignment copolymer films has been developed. However, an alignment performance of the photo alignment method may be influenced by organic light emitting elements when the photo alignment method is applied to form an alignment layer on a substrate having the organic light emitting elements because an uniformity of the UV light irradiating on the substrate will be influenced by the organic light emitting elements. Besides, an ion beam or a high-energy laser may be used to hit the surface of the polymer film from a specific angle in order to form the liquid crystal alignment layer, but in this method, the organic light emitting elements on the substrate may be damaged by this process, and the process equipments are expensive and not easy to be commercialized.

### SUMMARY OF THE INVENTION

The present invention provides a method of forming a liquid crystal alignment layer, a method of forming a display panel and a display panel, which uses organic molecules having carboxyl group elements and alkyl group elements to form a liquid crystal alignment layer at ambient temperature, thereby achieving a low-temperature manufacturing process, and improving the application range of the liquid crystal alignment layer.

To achieve the purpose mentioned above, the present invention provides a method of forming a liquid crystal alignment layer comprising the following steps: first, a substrate is provided. Then, a base layer is formed on the substrate. Afterwards, a first liquid crystal alignment layer is formed on the base layer. The first liquid crystal alignment layer includes a plurality of first organic molecules. Each of the first organic molecules includes a first carboxyl group part and a first alkyl group part.

To achieve the purpose mentioned above, the present invention provides a method of forming a display panel, comprising the following steps: first, a substrate and a counter substrate are provided; then, a base layer is formed on the substrate, and a first liquid crystal alignment layer is formed on the base layer, wherein the first liquid crystal alignment layer comprises a plurality of first organic molecules, and each of the first organic molecules includes a first carboxyl group part and a first alkyl group part; afterwards, a liquid crystal layer is formed between the substrate and the counter substrate.

To achieve the purpose mentioned above, the present invention provides a display panel, comprising a substrate and a counter substrate disposed opposite to the substrate, a liquid crystal layer disposed between the substrate and the counter substrate, and a first liquid crystal alignment layer disposed between the liquid crystal layer and the substrate, wherein the first liquid crystal alignment layer comprises a plurality of first organic molecules, and each of the first organic molecules includes a first carboxyl group part and a first alkyl group part.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing the method of forming the liquid crystal alignment layer according to the first preferred embodiment of the present invention.

FIG. 2 is a flow chart showing the method of forming the liquid crystal alignment layer according to the first preferred embodiment of the present invention.

FIG. 3 is a schematic diagram showing the method of forming the liquid crystal alignment layer according to the second preferred embodiment of the present invention.

FIG. 4 is a diagram showing the display panel according to the third preferred embodiment of the present invention.

FIG. 5 is a diagram showing the display panel according to the fourth preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

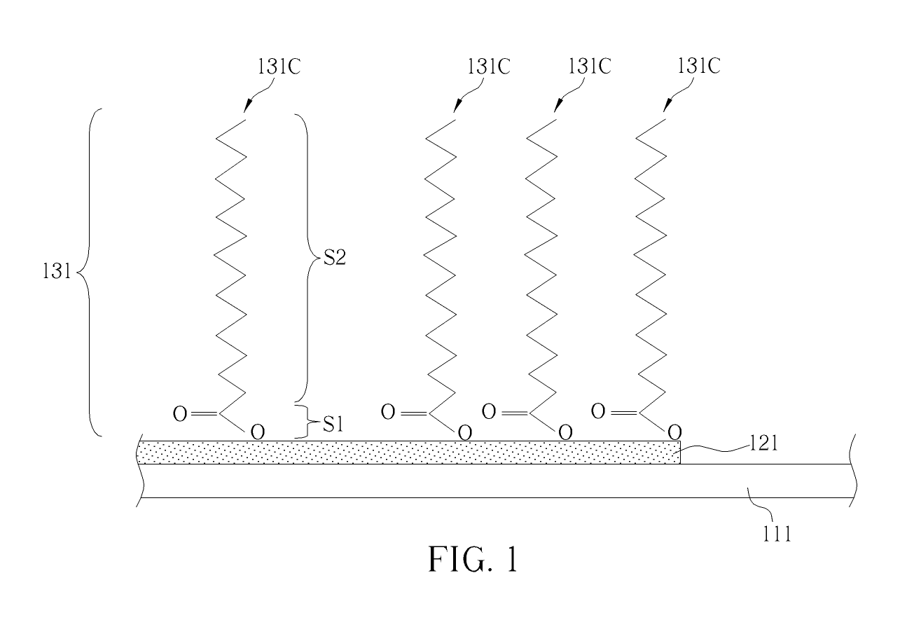

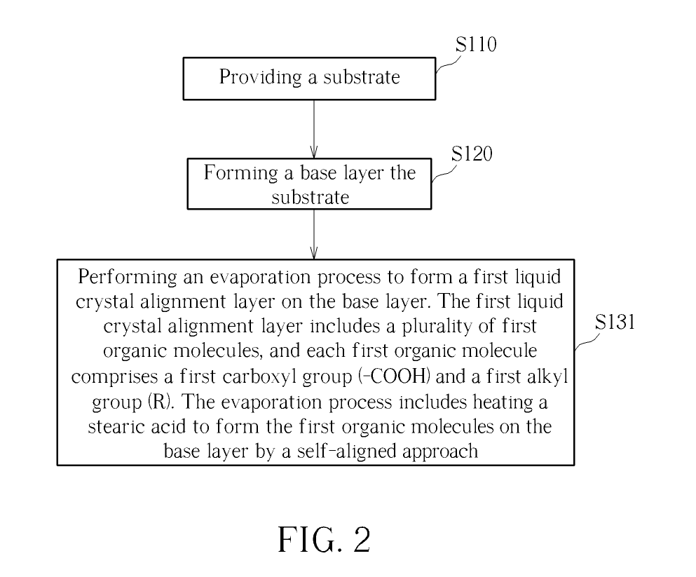

Please refer to FIG. 1 and FIG. 2; FIG. 1 is a schematic diagram showing the method of forming the liquid crystal alignment layer according to the first preferred embodiment of the present invention. FIG. 2 is a flow chart showing the method of forming the liquid crystal alignment layer according to the first preferred embodiment of the present invention. As shown in FIG. 1 and FIG. 2, the first preferred embodiment of the present invention provides a method of forming a liquid crystal alignment layer comprising the following steps. First, the step S110 is performed, i.e. a substrate 111 is provided. The substrate 111 may include a rigid substrate such as a glass substrate and a ceramic substrate, a flexible substrate such as a plastic substrate, or other substrates made of suitable materials. Then, the step S120 is carried out, i.e. a base layer 121 is formed on the substrate 111. In this embodiment, the material of the base layer 121 includes metal such as aluminum (Al), iron (Fe), nickel (Ni) and titanium (Ti), metal oxides such alumina, iron oxide, titanium oxide, indium tin oxide (ITO), indium zinc oxide (IZO), aluminum zinc oxide (AZO) and indium gallium zinc oxide (IGZO), or other suitable materials. A first liquid crystal alignment layer 131 is then formed on the base layer 121, wherein the first liquid crystal alignment layer 131 includes a plurality of first organic molecules 131C, and each first organic molecule 131C comprises a first carboxyl group (—COOH) S1 and a first alkyl group (R) S2.

More specifically, the first liquid crystal alignment layer 131 of this embodiment may be formed on the base layer 121 through an evaporation process (step S131). The evaporation process preferably includes heating an evaporation source (in this embodiment, the evaporation source is a stearic acid) to form the first organic molecules 131C on the base layer 121 by a self-aligned approach, but not limited thereto. Each of the first carboxyl group S1 in the first organic molecules 131C bonds with the base layer 121, and connects the base layer 121. Therefore, the surfaces without base layer 121 formed on the substrate 111 will not be connected to the first organic molecules 131C, so the self-aligned approach mentioned above can be achieved for forming the first liquid crystal alignment layer 131. Besides, the first organic molecule 131C of the present embodiment preferably is a carboxylic acid or other molecules with carboxylic acid radicals. Thanks to the connection between the first carboxyl group S1 and the base layer 121, each first alkyl group S2 of the first organic molecules 131C can extend from a direction opposite to the substrate 111. Each first alkyl group S2 is arranged in a consistent direction and the liquid crystal molecules (not shown in FIG. 1 and FIG. 2) may be aligned accordingly. In other words, the first carboxyl group S1 is disposed between the first alkyl group S2 and the base layer 121. It is worth noting that the method of the present invention does not require heating the substrate 111 at high temperature and doesn't require physical contacts to the substrate 111 that could cause damages on the substrate, so it can achieve a manufacturing process with a low-temperature and improving the application range of the liquid crystal alignment layer 131.

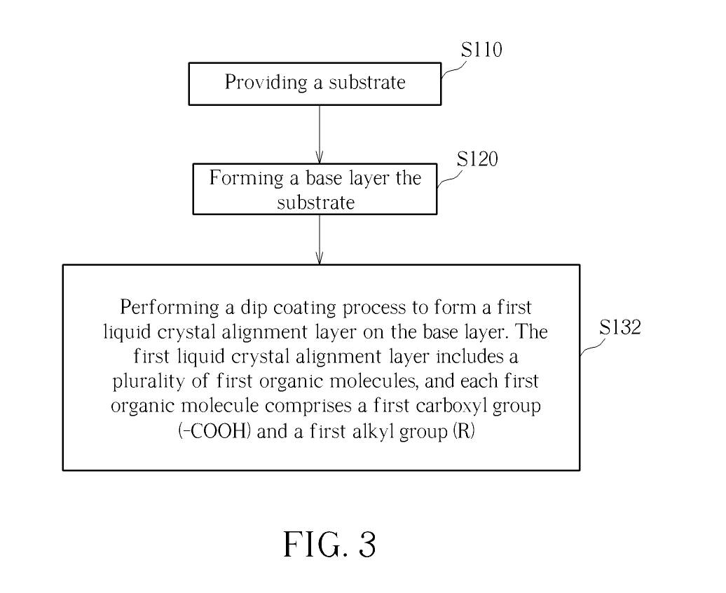

Please refer to FIG. 3 and FIG. 1 together. FIG. 3 is a schematic diagram showing the method of forming the liquid crystal alignment layer according to the second preferred embodiment of the present invention. The difference between the method of this embodiment and the first embodiment is that the liquid crystal alignment layer 131 is formed on the base layer 121 during the step S132 after the step S120 is performed through a dip coating process. The first liquid crystal alignment layer 131 includes a plurality of first organic molecules 131C, each first organic molecule 131C comprises a first carboxyl group S1 and a first alkyl group S2. In other words, the formation of the first liquid crystal alignment layer 131 of the present invention preferably comprises the evaporation process of the first preferred embodiment or the dip coating process of the second embodiment, but not limited thereto, other methods may be used to form the first liquid crystal alignment layer 131 according to actual requirements. Besides, the method of the present invention does not require heating the substrate 111 at a high temperature or physical contacts to the substrate 111 either, thereby avoiding deterioration of the substrate in both cases, thereby achieving a low-temperature manufacturing process, and improving the application range of the liquid crystal alignment layer 131.

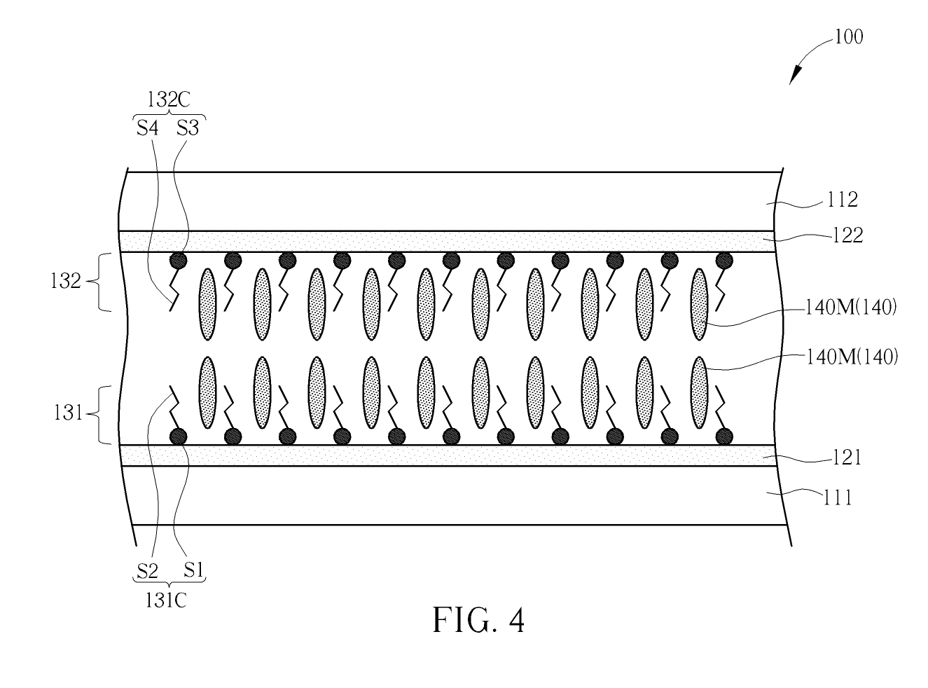

Please refer to FIG. 4; FIG. 4 is a diagram showing the display panel according to the third preferred embodiment of the present invention. As shown in FIG. 4, this embodiment provides a method of forming a display panel, comprising the following steps. First, the substrate 111 and a counter substrate 112 are provided. Then, the base layer 121 is formed on the substrate 111. Afterwards, the first liquid crystal alignment layer 131 is formed on the base layer 121. The first liquid crystal alignment layer 131 includes a plurality of first organic molecules 131C, wherein each first organic molecule 131C comprises a first carboxyl group S1 and a first alkyl group S2. A liquid crystal layer 140 is then formed between the substrate 111 and the counter substrate 112. The formation method and the material of the first liquid crystal alignment layer 131 have been described in the first and second embodiment and will not be redundantly described here again. It is worth noting that a second liquid crystal alignment layer 132 may further be formed on the counter substrate 112 in the manufacturing method of this embodiment, wherein the second liquid crystal alignment layer 132 comprises a plurality of second organic molecules 132C, and each second organic molecules 132C comprises a second carboxyl group S3 and a second alkyl group S4. The material and the formation method of the second liquid crystal alignment layer 132 is preferably similar to the that of first liquid crystal alignment layer 131, but not limited thereto. In other words, the second organic molecules 132C are preferably similar to the first organic molecules 131C, the second alkyl group S4 and the second carboxyl group S3 have the same composition as the composition of the first alkyl group S2 and the first carboxyl group S1 respectively, but not limited thereto. The composition of the second alkyl group S4 may be adjusted to be different from the first alkyl group S2 for generating other required alignment effects. In addition, in other preferred embodiments of the present invention, the second liquid crystal alignment layer 132 may be formed through others method; in other words, the second liquid crystal alignment layer 132 may include a polyimide (PI) alignment layer or other polymer alignment layers formed through physical or optical alignment methods.

It is worth noting that the liquid crystal layer 140 of the present embodiment comprises a plurality of liquid crystal molecules 140M, wherein each liquid crystal molecule 140M is preferably a vertical alignment (VA) mode liquid crystal molecule, but not limited thereto. Besides, the substrate 111 of the embodiment is preferably an array substrate, the counter substrate 112 is preferably a color filter substrate, but not limited thereto. The manufacturing of this embodiment may further comprise forming a base layer 122 on the counter substrate 112 before the second liquid crystal alignment layer 132 is formed, and the material of the base layer 122 is adjusted so as to have the second carboxyl group S3 of the second organic molecules 132C bond with the base layer 122. The base layer 122 may be regarded as a common electrode, and the base layer 122 preferably comprises metal oxide such as alumina, iron oxide, titanium oxide, indium tin oxide, indium zinc oxide, aluminum zinc oxide, indium gallium zinc, but not limited thereto. In addition, the substrate 111 preferably comprises an array substrate, which may include a switch element (not shown) such as a thin film transistor, and the base layer 121 can also be a pixel electrode for driving the liquid crystal molecules 140M. In other words, the base layer 121 of the present embodiment can be used as the bonding layer to the first organic molecules 131C, and the base layer 121 may also used as the pixel electrode to drive the liquid crystal molecules 140M of the display panel 100. Therefore, the method of this embodiment does not require additional processes to form the base layer 121 and is compatible with the general liquid crystal display panel manufacturing process.

The display panel 100 shown in FIG. 4 can be achieved by the manufacturing method mentioned above. The display panel 100 comprises the substrate 111, the counter substrate 112, the liquid crystal layer 140, the base layer 121, the first liquid crystal alignment layer 131, the base layer 122 and the second liquid crystal alignment layer 132. The substrate 111 is disposed opposite to the counter substrate 112; the liquid crystal layer 140 is disposed between the substrate 111 and the counter substrate 112. The first liquid crystal alignment layer 131 is disposed between the liquid crystal layer 140 and the substrate 111, the second liquid crystal alignment layer 132 is disposed between the counter substrate 112 and the liquid crystal layer 140, the base layer 121 is disposed between the substrate 111 and the first liquid crystal alignment layer 131, and the base layer 122 is disposed between the counter substrate 112 and the second liquid crystal alignment layer 132. It is worth noting that each first carboxyl group S1 of the first organic molecules 131C is connected to the base layer 121; each second carboxyl group S3 of the second organic molecules 132C is connected to the base layer 122. Therefore, each first alkyl group S2 of the first organic molecules 131C and each second alkyl group S4 of the second organic molecules 132C may extend toward the liquid crystal layer 140 respectively, thereby providing a vertical alignment effect to the liquid crystal molecules 140M. In other words, the present embodiment of the display panel 100 can be regarded as a liquid crystal display panel, but not limited thereto.

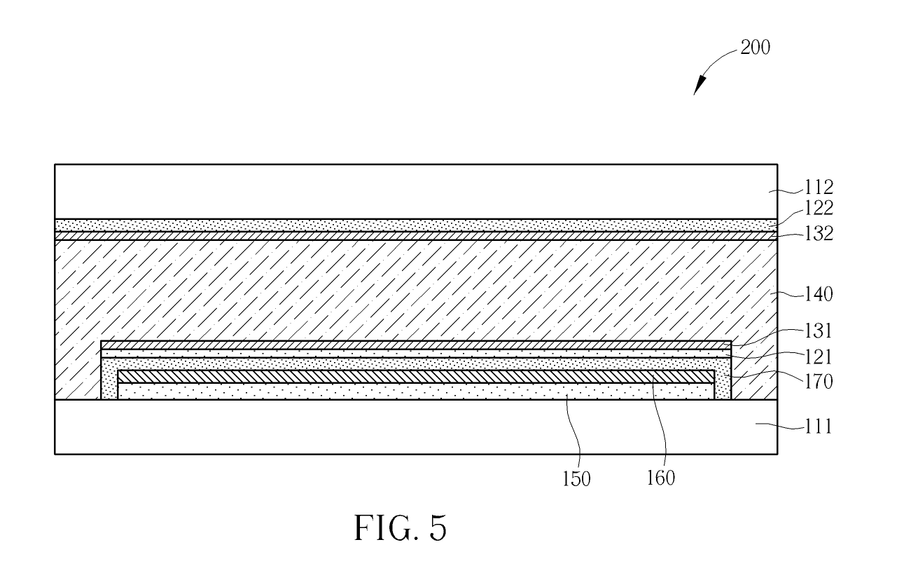

Please refer to FIG. 5; FIG. 5 is a diagram showing a display panel according to the fourth preferred embodiment of the present invention. As shown in FIG. 5, the embodiment provides a display panel 200, and the difference from the third embodiment is that the display panel 200 further includes an organic light emitting element 150 and a protective layer 170. The organic light emitting element 150 is disposed between the substrate 111 and the first liquid crystal alignment layer 131, and the protective layer 170 is disposed between the organic light emitting element 150 and the first liquid crystal alignment layer 131. In other words, the method of forming the display panel of the present embodiment may further include forming an organic light emitting element 150 and the protective layer 170 on the substrate 111 before the base layer 121 is formed, so that the protective layer 170 covers the organic light emitting element 150 and protects it. The base layer 121 is disposed on the protection layer on top of the protective layer 170 in order to assist the formation of the first liquid crystal alignment layer 131. The display panel 200 may further include a cathode electrode 160 disposed between the organic light emitting element 150 and the protective layer 170 .The substrate 111 of the present embodiment is preferably an array substrate, and the counter substrate 112 is preferably a color filter on array (COA) substrate. It is worth noting that in the display panel 200 of the present embodiment the substrate 111 which is an array substrate and the cathode electrode 160 may be used to drive the organic light emitting element 150 and present a display effect. In the display panel 200, the base layer 121 and the base layer 122 may also be used to drive the liquid crystal layer 140 and present another display effect.

The base layer 121 of this embodiment can be regarded as a common electrode and the base layer 122 can be regarded as a pixel electrode, but not limited thereto. In other words, the display panel 200 of the present embodiment can be regarded as a dual-functions display panel having a liquid crystal display functions and an organic light emitting display function, and the display panel 200 may switch between a liquid crystal display mode and an organic light emitting display mode or present both modes simultaneously according to specific requirements. For example, when the cathode electrode 160 is a translucent material, the organic light emitting element 150 may be a white organic light-emitting element for acting as a white back light source to produce the display effect with the liquid crystal layer 140 and the counter substrate 112 which is a COA substrate. The liquid crystal layer 140 may not be driven, but only the organic light emitting element 150 is driven to display images. In another case, when the cathode electrode 160 is a reflective material, the organic light emitting element 150 may emit light downwards, and the liquid crystal layer 140 may form a reflective liquid crystal display effect by using the cathode electrode 160. In addition, since the formation method of the first liquid crystal alignment layer 131 of the present invention does not require high-temperature heating of the substrate 111 and does not provoke physical contact damage either, the first liquid crystal alignment layer 131 can be formed on the organic light emitting element 150 and the protective layer 170 without influencing the quality of the organic light emitting element 150.

In summary, the method of the present invention includes a liquid crystal alignment film made of organic molecules with a carboxyl group and an alkyl group through an evaporation process or a dip coating process at room temperature, a low-temperature process is performed which improves the application range of the liquid crystal alignment . Furthermore, the method of forming the liquid crystal alignment layer is further employed in the method of forming the dual-function display panel having the liquid crystal display function and the organic light emitting display function.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a liquid crystal alignment layer, comprising:
providing a substrate;
forming a base layer on the substrate; and
forming a first liquid crystal alignment layer on the base layer, wherein the first liquid crystal alignment layer comprises a plurality of first organic molecules, and each of the first organic molecules includes a first carboxyl group part and a first alkyl group part.

2. The method of claim 1, wherein a step of forming the first liquid crystal alignment layer comprises performing an evaporation process or a dip coating process.

3. The method of claim 2, wherein the evaporation process comprises heating a stearic acid to form the first organic molecules on the base layer by a self-aligned approach.

4. The method of claim 1, wherein each of the first carboxyl group parts in the organic molecules is connected to the base layer.

5. The method of claim 1, wherein the base layer comprises metal or metallic oxide.

6. A method of forming a display panel, comprising:
providing a substrate and a counter substrate;
forming a base layer on the substrate;
forming a first liquid crystal alignment layer on the base layer, wherein the first liquid crystal alignment layer comprises a plurality of first organic molecules, and each of the first organic molecules includes a first carboxyl group part and a first alkyl group part; and
forming a liquid crystal layer between the substrate and the counter substrate.

7. The method of claim 6, wherein a step of forming the first liquid crystal alignment layer comprises performing an evaporation process or a dip coating process.

8. The method of claim 7, wherein the evaporation process comprises heating a stearic acid to form the first organic molecules on the base layer by a self-aligned approach.

9. The method of claim 6, wherein each of the first carboxyl group parts in the organic molecules is connected to the base layer.

10. The method of claim 6, wherein the base layer comprises metal or metallic oxide.

11. The method of claim 6, wherein the liquid crystal layer comprises a plurality of vertical alignment (VA) mode liquid crystal molecules.

12. The method of claim 6, wherein the substrate comprises an array substrate, and the counter substrate comprises a color filter substrate.

13. The method of claim 6, further comprising forming a second liquid crystal alignment layer on the counter substrate, wherein the second liquid crystal alignment layer comprises a plurality of second organic molecules, and each of the second organic molecules includes a second carboxyl group part and a second alkyl group part.

14. The method of claim 6, further comprising forming an organic light emitting element and a protective layer on the substrate, wherein the protective layer covers the organic light emitting element disposed on the substrate, and the base layer is formed after the protective layer is formed.

15. A display panel, comprising:
a substrate and a counter substrate disposed opposite to the substrate;
a liquid crystal layer, disposed between the substrate and the counter substrate; and
a first liquid crystal alignment layer, disposed between the liquid crystal layer and the substrate, wherein the first liquid crystal alignment layer comprises a plurality of first organic molecules, and each of the first organic molecules includes a first carboxyl group part and a first alkyl group part.

16. The display panel of claim 15, further comprising a base layer disposed between the substrate and the first liquid crystal alignment layer, and the base layer comprises metal or metallic oxide.

17. The display panel of claim 16, wherein each of the first carboxyl group parts in the organic molecules is connected to the base layer.

18. The display panel of claim 15, wherein the liquid crystal layer comprises a plurality of vertical alignment (VA) mode liquid crystal molecules.

19. The display panel of claim 15, wherein the substrate comprises an array substrate, and the counter substrate comprises a color filter substrate.

20. The display panel of claim 15, wherein the substrate comprises an array substrate, and the counter substrate comprises a color filter on array (COA) substrate.

21. The display panel of claim 15, further comprising a second liquid crystal alignment layer disposed between the counter substrate and the liquid crystal layer, wherein the second liquid crystal alignment layer comprises a plurality of second organic molecules, and each of the second organic molecules includes a second carboxyl group part and a second alkyl group part.

22. The display panel of claim 15, further comprising an organic light emitting element disposed between the substrate and the first liquid crystal alignment layer.

23. The display panel of claim 22, further comprising a protective layer disposed between the light emitting element and the first liquid crystal alignment layer.
